(19) United States
(12) Patent Application Publication
(10) Pub. No.: US 2010/0133695 A1
(43) Pub. Date: Jun. 3, 2010

(54) ELECTRONIC CIRCUIT WITH EMBEDDED MEMORY

(76) Inventor: Sang-Yun Lee, Beaverton, OR (US)

Correspondence Address: SCHMEISER OLSEN & WATTS, 18 E UNIVERSITY DRIVE, SUITE # 101, MESA, AZ, 85201, US

(21) Appl. No.: 12/637,559

(22) Filed: Dec. 14, 2009

Related U.S. Application Data
(63) Continuation-in-part of application No. 12/040,642, filed on Feb. 29, 2008.
Application No. 12/040,642 is a continuation-in-part of application No. 11/092,498, filed on Mar. 29, 2005, now Pat. No. 7,470,142.
Application No. 11/092,498 is a continuation-in-part of application No. 11/092,499, filed on Mar. 29, 2005, now Pat. No. 7,470,598.
Application No. 11/092,499 is a continuation-in-part of application No. 11/092,500, filed on Mar. 29, 2005.
Application No. 11/092,500 is a continuation-in-part of application No. 11/092,501, filed on Mar. 29, 2005.
Application No. 11/092,501 is a continuation-in-part of application No. 11/092,521, filed on Mar. 29, 2005, now Pat. No. 7,633,162.
Application No. 11/092,521 is a continuation-in-part of application No. 11/180,286, filed on Jul. 12, 2005.
Application No. 11/180,286 is a continuation-in-part of application No. 11/378,059, filed on Mar. 17, 2006.
Application No. 11/378,059 is a continuation-in-part of application No. 11/606,523, filed on Nov. 30, 2006.
Application No. 11/606,523 is a continuation-in-part of application No. 10/873,969, filed on Jun. 21, 2004, now Pat. No. 7,052,941.
Application No. 10/873,969 is a continuation-in-part of application No. 11/873,719, filed on Oct. 17, 2007.
Application No. 11/873,719 is a continuation-in-part of application No. 11/873,851, filed on Oct. 17, 2007.
Application No. 11/873,851 is a continuation-in-part of application No. 11/873,769, filed on Oct. 17, 2007.
Application No. 11/873,769 is a continuation-in-part of application No. 12/475,294, filed on May 29, 2009.
Application No. 12/475,294 is a continuation of application No. 12/470,344, filed on May 21, 2009.
Application No. 12/470,344 is a continuation-in-part of application No. 11/873,969, filed on Oct. 17, 2007.

(30) Foreign Application Priority Data
Jan. 12, 2003 (KR) 10-2003-0047515
Jun. 24, 2003 (KR) 10-2003-0040920
May 21, 2008 (KR) 10-2008-0046991
May 30, 2008 (KR) 10-2008-50946
Dec. 5, 2008 (KR) 10-2008-0100892
Dec. 5, 2008 (KR) 10-2008-0100893
Dec. 5, 2008 (KR) 2008-123595

(51) Int. Cl. H01L 23/522

(52) U.S. Cl. 257/773; 257/758; 257/E23.142

(57) ABSTRACT

Circuitry includes first and second circuits spaced apart by an interconnect region. The interconnect region includes a first interconnect, and the second circuit includes a stack of semiconductor layers. The first interconnect extends between the first and second circuits to provide communication therebetween. The second circuit operates as a memory circuit.

### CROSS-REFERENCE TO RELATED APPLICATIONS

This application is a continuation-in-part of, and claims the benefit of, U.S. patent application Ser. No. 11/092,521, which was filed on Mar. 29, 2005 by the same inventor, the contents of which are incorporated by reference as though fully set forth herein.

This application is a continuation-in-part of, and claims the benefit of, U.S. patent application Nos.:

Ser. No. 12/165,445; and

Ser. No. 12/165,475;

which in turn are divisionals of, and claim the benefit of, U.S. patent application Ser. No. 11/092,499 (now U.S. Pat. No. 7,470,598), filed on Mar. 29, 2005, which is a continuation-in-part of, and claims the benefit of, claims the benefit of U.S. patent application Ser. No. 10/873,969 (now U.S. Pat. No. 7,052,941), filed on Jun. 21, 2004.

This application is a continuation-in-part of, and claims the benefit of, U.S. patent application Nos.:

Ser. No. 11/092,500, filed on Mar. 29, 2005,

Ser. No. 11/092,501, filed on Mar. 29, 2005;

Ser. No. 11/092,521, filed on Mar. 29, 2005;

Ser. No. 11/180,286, filed on Jul. 12, 2005;

Ser. No. 11/378,059, filed on Mar. 17, 2006; and

Ser. No. 11/606,523, filed on Nov. 30, 2006;

which in turn are continuation-in-parts of, and claim the benefit of, U.S. patent application Ser. No. 10/873,969 (now U.S. Pat. No. 7,052,941), filed on Jun. 21, 2004, which claims the benefit of Republic of Korea Patent Application Nos. 10-2003-0040920 and 10-2003-0047515, filed on Jun. 24, 2003 and Jul. 12, 2003, respectively, the contents of all of which are incorporated herein by reference in their entirety.

This application is also a continuation-in-part of, and claims the benefit of, U.S. patent application Nos.:

Ser. No. 11/873,719, filed on Oct. 17, 2007; and

Ser. No. 11/873,851, filed on Oct. 17, 2007;

which in turn are divisionals of, and claim the benefit of, U.S. patent application Ser. No. 11/092,521, which is a continuation-in-part of, and claims the benefit of, U.S. patent application Ser. No. 10/873,969 (now U.S. Pat. No. 7,052,941), filed on Jun. 21, 2004, which claims the benefit of Republic of Korea Patent Application Nos. 10-2003-0040920 and 10-2003-0047515, filed on Jun. 24, 2003 and Jul. 12, 2003, respectively, the contents of both of which are incorporated herein by reference in their entirety.

This application is also a continuation-in-part of, and claims the benefit of, U.S. patent application Ser. No. 11/873,769, filed on Oct. 17, 2007, which in turn is a divisional of, and claims the benefit of, U.S. patent application Ser. No. 11/092,500, which is a continuation-in-part of, and claims the benefit of, U.S. patent application Ser. No. 10/873,969 (now U.S. Pat. No. 7,052,941), filed on Jun. 21, 2004, which claims the benefit of Republic of Korea Patent Application Nos. 10-2003-0040920 and 10-2003-0047515, filed on Jun. 24, 2003 and Jul. 12, 2003, respectively, the contents of both of which are incorporated herein by reference in their entirety.

### BACKGROUND OF THE INVENTION

1. Field of the Invention

The present invention relates generally to semiconductor circuitry and, more particularly, to circuitry which includes memory devices.

2. Description of the Related Art

Advances in semiconductor manufacturing technology have provided computer chips with integrated circuits that include many millions of active and passive electronic devices, along with the interconnects to provide the desired circuit connections. As is well-known, most integrated circuits include laterally oriented active and passive electronic devices that are carried on a single major surface of a substrate. Active devices typically include transistors and passive devices typically include resistors, capacitors, and inductors. However, these laterally oriented devices consume significant amounts of chip area.

For example, a typical computer system includes a main computer chip with a processor circuit, a control circuit, and a memory cache that are carried on a single major surface of a substrate. The typical computer system also includes main memory which is positioned on a separate memory chip outside the main computer chip. Since the memory cache is positioned on the same substrate as the processor and control circuits in the main computer chip, it is often referred to as embedded memory.

The memory cache typically includes fast and expensive memory cells, such as Static Random Access Memory (SRAM) cells, and the main memory typically includes slower and less expensive Dynamic Random Access Memory (DRAM) cells. Both SRAM and DRAM cells are larger than the devices included in the processor and control circuits, with SRAM cells being much larger than DRAM cells. As is well-known in the art, cache memory (L1 cache or L2 cache, for example) is used to store information from a slower storage medium or subsystem, such as the main memory or peripherals like hard disks and CD-ROMs, that is accessed frequently to increase the operation of the main computer chip.

One reason the operation of the main computer chip is increased because its idle time is reduced. For example, when the processor circuit accesses the main memory, it does so in about 60 nanoseconds (ns). However, a typical processor circuit can have cycle times of about 2 nanoseconds. Hence, there are about 30 wasted cycles while the processor circuit accesses the main memory. As a result, the processor circuit is idle for many cycle times while it accesses the main memory.

The processor circuit, however, can access the cache memory in about 10 ns to 30 ns, so the idle time is significantly reduced if the information needed is stored in the cache memory. The access time of the processor circuit to a hard disk is even slower at about 10 milliseconds (ms) to 12 ms, and the access time to a CD-ROM drive is about 10 times greater than this. Hence, cache memory uses a small amount of fast and expensive memory to allow the processor circuit faster access to information normally stored by a large amount of slower, less-expensive memory.

With this in mind, it seems like the operation of the computer system can be increased even more by increasing the size of the cache memory so that it operates as the main memory or by embedding the main memory on the same substrate as the processor and control circuit and eliminating the cache memory altogether. However, there are several problems with doing this.

One problem with doing this is cost. As mentioned above, the SRAM cells included in cache memory are larger and expensive, so increasing the size of the cache memory would significantly increase the cost of the computer chip. DRAM cells are less expensive and smaller, but to embed them with the main computer chip will still significantly increase the cost. One reason the cost increases for both embedded SRAM and DRAM cells is because the number of masks needed to fabricate the main computer chip increases. For example, to embed SRAM and DRAM memory cells with the main computer chip would require about 3-4 and 6-8 extra masks, respectively. This is because the masks used to fabricate the processor and control circuitry are not compatible with the masks used to fabricate SRAM and DRAM memory cells. Another reason the cost increases is because, as discussed below, the yield in manufacturing computer chips decreases as the size of the computer chip increases.

Another problem is that in today's computer systems, the size of the main memory is much larger than the size of the cache memory. For example, in current state of the art systems, the main memory can store 256 MB to 1 GB in a single memory chip, but the cache memory can only store about 1 MB to 2 MB. This is because the size of the memory circuitry needed to store information in SRAM is much larger than that needed for DRAM. A conventional SRAM circuit includes six transistors to store one bit of information and a conventional DRAM circuit includes one transistor and one capacitor, which tend to be large, to store one bit of information.

For example, the size of a conventional embedded SRAM cell is about 70-120 F² and the size of a conventional DRAM memory cell is about 15 F². As is known in the art, 1 F is the minimum photolithographic feature size. Hence, if the computer chip is being fabricated using 90 nm lithography, then 1 F corresponds to 90 nm and 1 F² corresponds to an area that it 90 nm by 90 nm in size. If the computer chip is being fabricated using 60 nm lithography, then 1 F corresponds to 60 nm and 1 F² corresponds to an area that it 60 nm by 60 nm in size. Thus, to increase the size of the cache memory by increasing the number of SRAM cells included therein would significantly increase the size of the computer chip and decrease its yield. Further, most of the area on the computer chip will be occupied by memory circuitry instead of processor and control circuitry.

This presents several problems. As mentioned above, one problem is that the yield of computer chips in a manufacturing run decreases as their size increases. As is well-known in the art, several computer chips are fabricated from a single large wafer in a run. The individual computer chips carried by the wafer are typically referred to as die. Once the computer chips are fabricated, the die in the wafer are diced to provide separate chips. A wafer, however, has defects distributed throughout it surface which can negatively impact the operation of the computer chips. If the computer chip is larger in size, then it is more likely to include a defect from the wafer and if the computer chip is smaller in size, then it is less likely to include a defect from the wafer. Hence, smaller computer chips are less likely to be defective. Further, if the computer chip is smaller in size, then more of them can be fabricated from a single wafer, which also decreases costs. Hence, smaller computer chips increase the yield and decrease the costs.

Another problem is that it is typically desirable to increase the number of devices included in the processor and control circuitry so that the processor can operate faster and perform more complicated operations. It is desirable for computer chips to be fast so they can process more data in a given amount of time. The speed of operation of a computer chip is typically measured in the number of instructions per second it can perform.

Computer chips can be made to process more data in a given amount of time in several ways. In one way, the computer chip can include devices which are smaller, but this requires advances in lithography and increasingly expensive manufacturing equipment. As discussed above, they can also be made faster by decreasing the time it takes to perform certain tasks, such as storing or retrieving information to and from memory or other peripherals and subsystems.

Computer chips can also be made faster by increasing the number of devices included therein so that more information can be processed in a given period of time. For example, if one processor operates on 32-bit data, then another processor that operates on 64-bit data can process information twice as fast because it can perform more instructions per second. However, the 64-bit processor will need more devices since there are more bits to process at a given time. Hence, if most of the area on the computer chip is occupied by memory cells, then there is less area for the processor and control circuitry to process data with a higher number of bits. The total area of the computer chip can be increased, but as discussed above, this decreases the yield and increases the cost.

Accordingly, it is highly desirable to provide new structures and methods for fabricating computer chips which operate faster and cost effective to fabricate.

### BRIEF SUMMARY OF THE INVENTION

The present invention is directed to bonded semiconductor structures. The novel features of the invention are set forth with particularity in the appended claims. The invention will be best understood from the following description when read in conjunction with the accompanying drawings.

### BRIEF DESCRIPTION OF THE DRAWINGS

FIG. 1a is a perspective view of a partially fabricated semiconductor structure, which is fabricated using growth.

FIG. 1b is a perspective view of a substrate and grown semiconductor layer of the semiconductor structure of FIG. 1a.

FIG. 1c is a side view of the semiconductor structure of FIG. 1b.

FIG. 2a is a perspective view of a partially fabricated semiconductor structure, which is fabricated using bonding.

FIG. 2b is a perspective view of substrates of the semiconductor structure of FIG. 2a bonded to each other.

FIG. 2c is a side view of the substrates of the bonded semiconductor structure of FIG. 2b bonded to each other, as shown in FIG. 2b.

FIG. 3 is a top view of a computer chip, with one processor positioned near a control circuit.

FIG. 4 is a sectional view of the computer chip of FIG. 3 taken along a cut-line 4-4 of FIG. 3.

FIG. 5a is a perspective view of a computer chip with memory circuit positioned on the same substrate as the processor and control circuits.

FIGS. 5b-5d are perspective views of different computer chips in which the memory circuit is positioned above the processor and/or control circuits.

FIG. 6 is a more detailed view of one embodiment of the memory circuit of FIGS. 3 and 4.

FIG. 7 is a top view of a computer chip with multiple processors separated by a control circuit.

FIG. 8 is a sectional view of the computer chip of FIG. 7 taken along a cut-line 8-8 of FIG. 7.

FIG. 9 is a top view of another embodiment of a computer chip with multiple processor circuits and multiple control circuits.

FIG. 10 is a top view of another embodiment of a computer chip with multiple processor circuits with a control circuit.

FIG. 11 is a top view of another embodiment of a computer chip with multiple processors partially and multiple control circuits.

### DETAILED DESCRIPTION OF THE INVENTION

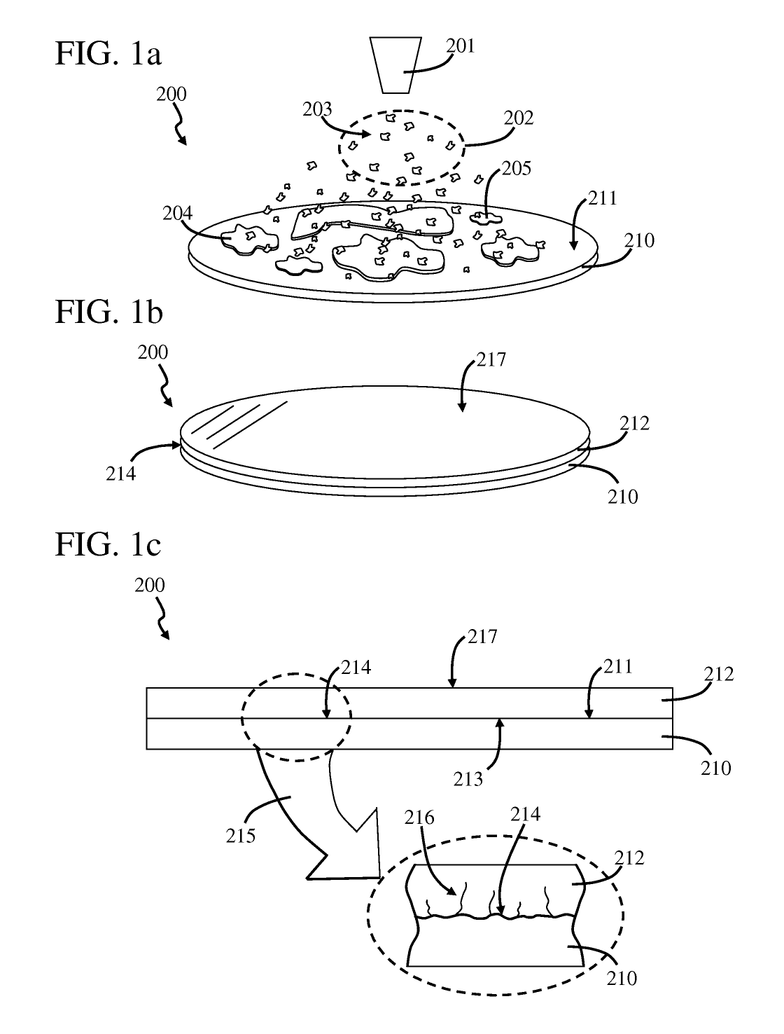

FIG. 1a is a perspective view of a partially fabricated grown semiconductor structure 200. It should be noted that in the following figures, like reference characters indicate corresponding elements throughout the several views. Grown semiconductor structure 200 includes a substrate 210. Substrate 210 can be of many different types, such as a semiconductor substrate.

In this embodiments, a gaseous semiconductor material 203 is provided from a growth material source 201 in a region 202 proximate to a substrate surface 211 of substrate 210. It should be noted that, in general, more than one material sources are used to provide growth material and process gases. However, one material source is shown in FIG. 1a for simplicity and ease of discussion.

Portions of gaseous semiconductor material 203 engage surface 211 to form agglomerated semiconductor material 204 and 205. Portions of gaseous semiconductor material 203 engage surface 211 to form a grown semiconductor layer 212 on surface 211 of substrate 210, as shown in FIG. 1b, and a growth interface 214, as shown in FIG. 1c. FIG. 1b is a perspective view of substrate 210 and grown semiconductor layer 212, and FIG. 1c is a side view of grown semiconductor structure 200, as shown in FIG. 1b. Grown semiconductor layer 212 can be formed on substrate 210 in many different ways, such as by chemical vapor deposition, molecular beam epitaxy and sputtering, among others. It should be noted that, if desired, another semiconductor layer can be grown on a surface 217 of semiconductor layer 212 so that a stack of semiconductor regions is formed. Surface 217 is opposed to substrate 210. More information regarding forming a stack of semiconductor regions is provided in some of the above-identified related applications.

As shown in FIG. 1c, a surface 213 of grown semiconductor layer 212 faces surface 211 of substrate 210. In particular, surface 213 is formed in response to the agglomeration of growth material on surface 211 so that a growth interface 214 is formed in response. In particular, growth interface 214 is formed in response to gaseous semiconductor material 203 agglomerating on surface 211. In this example, growth interface 214 is formed in response to agglomerated semiconductor material 204 and 205 forming on surface 211, as shown in FIG. 1a. In this way, a grown semiconductor structure is fabricated using growth.

As indicated by an indication arrow 215, a growth defect 216 is formed in response to forming growth interface 214. Growth defect 216 can be of many different types, such as a dislocation. It should be noted that, in general, a number of growth defects 216 are formed in response to forming growth interface 214. The quality of growth interface 216 increases and decreases in response to decreasing and increasing, respectively, the number of growth defects 216.

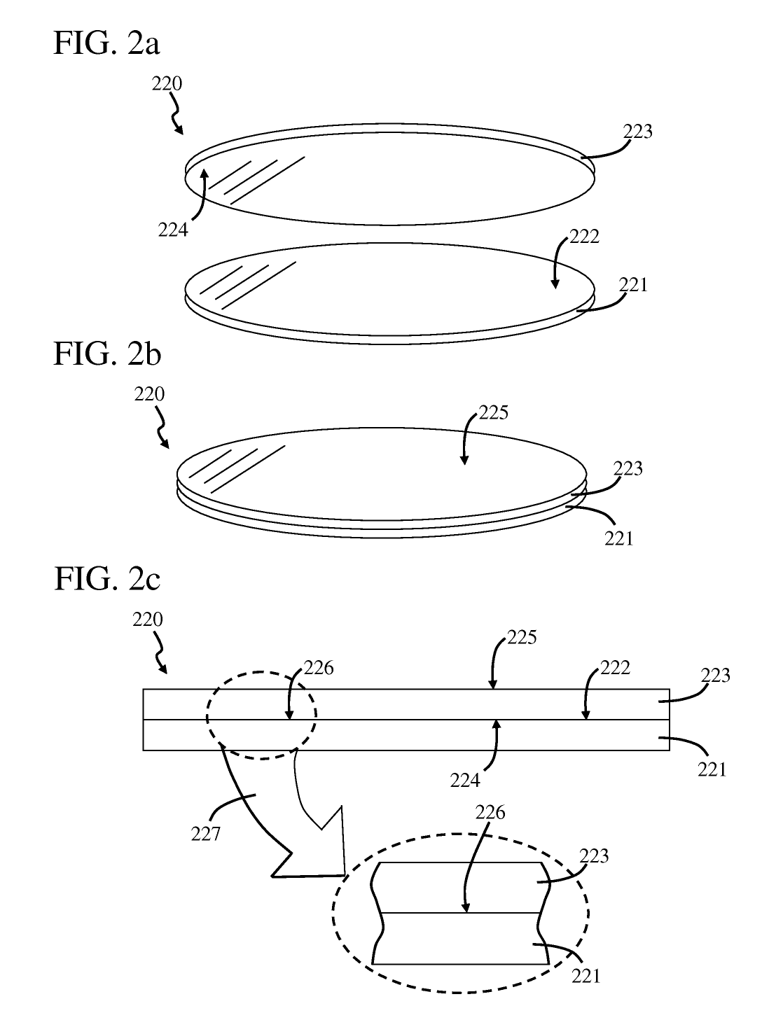

FIG. 2a is a perspective view of a partially fabricated bonded semiconductor structure 220. Bonded semiconductor structure 220 includes substrates 221 and 223. Substrates 221 and 223 can be of many different types, such as semiconductor substrates. Substrates 221 and 223 can include many different layer structures. For example, in some embodiments, substrates 221 and 223 each include conductive bonding layers adjacent to surfaces 222 and 224 of substrates 221 and 223, respectively.

In some embodiments, the semiconductor substrates discussed herein include semiconductor material. In some embodiments, the semiconductor substrate consists of semiconductor material. In some embodiments, the semiconductor substrate consists essentially of semiconductor material. The semiconductor material can be of many different types, such as silicon.

As shown in FIG. 2b, substrates 221 and 223 are moved towards each other so that a bonding interface 226 is formed in response, as shown in FIGS. 2b and 2c. In particular, surfaces 222 and 224 of substrates 221 and 223, respectively, are moved towards each other so that a bonding interface 226 is formed in response to surfaces 222 and 224 being engaged. FIG. 2b is a perspective view of substrates 221 and 223 bonded to each other, and FIG. 2c is a side view of substrates 221 and 223 bonded to each other, as shown in FIG. 2b.

In FIG. 2c, surface 222 of substrate 221 faces surface 224 of substrate 223. In particular, surface 221 engages surface 224 so that bonding interface 226 is formed in response. It should be noted that bonding interface 226 is not formed in response to gaseous semiconductor material engaging surface 222. In particular, bonding interface 226 is not formed in response to the agglomerated semiconductor material on surface 222. In this way, a bonded semiconductor structure is fabricated using bonding. As indicated by an indication arrow 227, a growth defect is not formed in response to forming bonding interface 226. It should be noted that a signal experiences less attenuation in response to flowing through a bonding interface, and experiences more attenuation in response to flowing through a growth interface. For example, a current decreases less in response to flowing through a bonding interface, and decreases more attenuation in response to flowing through a growth interface. Further, the noise of a signal increases more in response to flowing through a growth interface, and increases less in response to flowing through a bonding interface.

It should also be noted that portions of the semiconductor structures discussed below are fabricated using growth, and other portions are fabricated using bonding. It should also be noted that, if desired, substrate 223 can include a stack of semiconductor regions. The stack of semiconductor regions of substrate 223 can be formed in many different ways. More information regarding forming a stack of semiconductor regions is provided in some of the above-identified related applications.

More information regarding bonding and growth interfaces can be found in related U.S. patent application Ser. No. 11/606,523, which is referenced above. Information regarding bonding and growth interfaces can also be found in U.S. Pat. Nos. 5,152,857, 5,695,557, 5,980,633 and 6,534,382.

A bonding interface is an interface that is formed in response to bonding material layers together. In one example of forming a bonding interface, first and second material layers are formed as separate layers, and moved towards each other so they engage each other and the bonding interface is formed in response. In this way, a bonding interface is established. It should be noted that heat is generally applied to the first and/or second material layers to facilitate the formation of the bonding interface. In a metal-to-metal bonding interface, the first and second material layers that are bonded together are conductive materials, such as metals. In a metal-to-dielectric bonding interface, one of the first and second material layers is a conductive material, and the other one is a dielectric material. In a metal-to-semiconductor bonding interface, one of the first and second material layers is a conductive material, and the other one is a semiconductor material. It should be noted that, in some embodiments, bonding interface 226 includes a metal-to-metal bonding interface. In some embodiments, bonding interface 226 includes a metal-to-dielectric bonding interface. Further, in some embodiments, bonding interface 226 includes a metal-to-semiconductor bonding interface.

A growth interface is an interface that is formed in response to growing a material layer on another material layer. In one example of forming a growth interface, a third material layer is formed, and a fourth material layer is grown on the third material layer so that the growth interface is formed in response. In this way, a growth interface is established. Hence, when forming a growth interface, third and fourth material layers are not formed as separate layers, and moved to engage each other.

In a metal-to-metal growth interface, the third and fourth material layers are conductive materials, such as metals. In a metal-to-dielectric growth interface, one of the third and fourth material layers is a conductive material, and the other one is a dielectric material. In a metal-to-semiconductor growth interface, one of the third and fourth material layers is a conductive material, and the other one is a semiconductor material. In a dielectric-to-dielectric growth interface the third and fourth materials are dielectric materials.

It should be noted that, in general, it is difficult to establish a metal-to-semiconductor growth interface, wherein the semiconductor material is grown on the metal layer. Further, it is difficult to grow a crystalline semiconductor material layer on a metal layer using semiconductor growth techniques, such as chemical vapor deposition. In most instances, the metal layer is formed on the semiconductor material. It is difficult to grow semiconductor material on a metal layer because metal layers do not operate as a very good seed layer for the semiconductor material. Hence, a significant amount of the semiconductor material will not agglomerate on the metal layer.

It is difficult to grow crystalline semiconductor material on the metal layer because metal layers tend to not be crystalline, and semiconductor material tends to have the crystal structure of the material it is formed on. Hence, if a semiconductor material is formed on a metal layer that includes non-crystalline conductive material, then the semiconductor material will also have a non-crystalline crystal structure and poor material quality. Thus, it is useful to bond crystalline semiconductor material to a metal layer to form a metal-to-semiconductor bonding interface.

In general, bonding and growth interfaces have different types and amounts of defects. For example, dislocations often extend from a growth interface in the direction of material growth. The difference between bonding and growth interfaces can be determined in many different ways, such as by using Transmission Electron Microscopy (TEM) to determine the type and amount of defects proximate to the interface. Information regarding TEM can be found in U.S. Pat. Nos. 5,892,225, 6,531,697, 6,822,233 and 7,002,152.

It should be noted that substrate 223 includes an opposed surface 225 which is opposed to surface 224. In this embodiment, surface 225 is positioned away from bonding interface 226. In some embodiments, surface 225 is planarized. A surface can be planarized in many different ways, such as by using chemical mechanical polishing (CMP). In general, a surface is planarized in response to reducing its surface roughness. The roughness of a surface can be determined in many different ways, such as by using a profilometer. In some embodiments, surface 224 is planarized. Further, in some embodiments, surfaces 224 and 225 are planarized. It should be noted that surface 224 is planarized before bonding interface 226 is formed. It should be noted that surface 224 faces interconnect region 131 and bonding interface 226, and surface 225 faces away from interconnect region 131 and bonding interface 226.

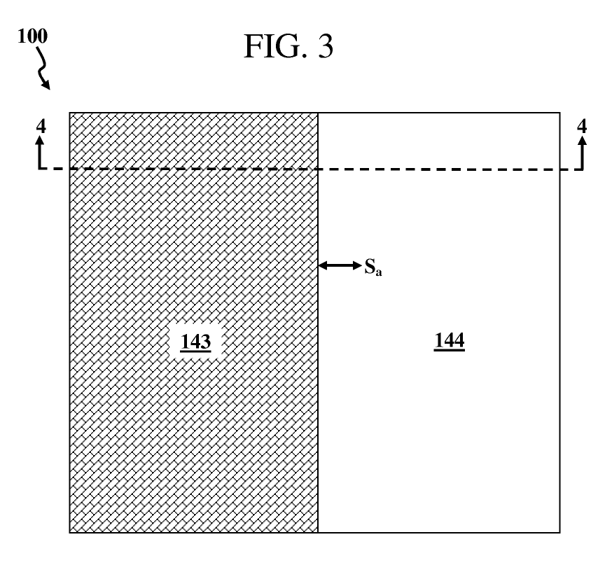

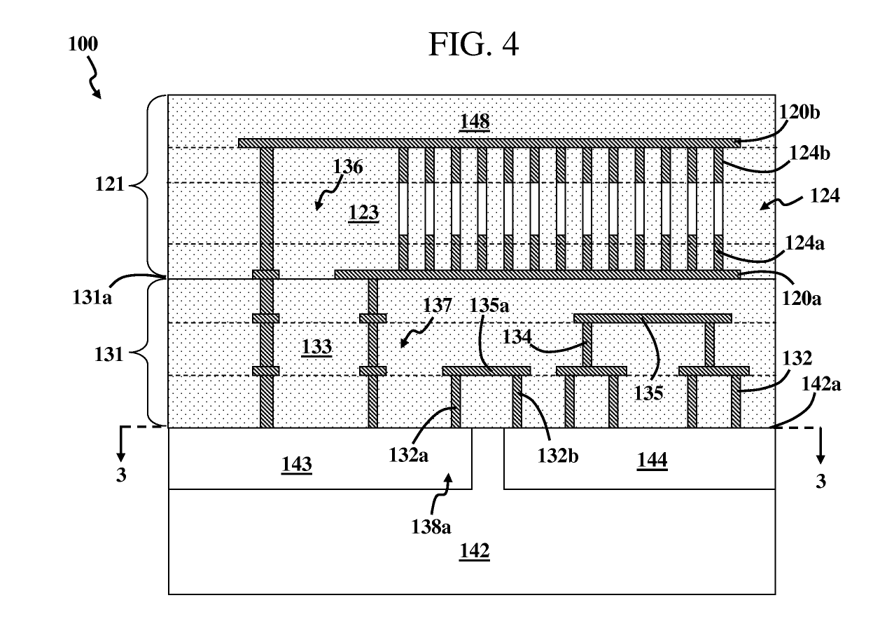

FIGS. 3 and 4 are top and cross sectional views of a computer chip 100 which includes circuitry. FIG. 3 is a top view taken along a cut-line 3-3 of FIG. 4 and FIG. 4 is a sectional view taken along a cut-line 4-4 of FIG. 3.

In this embodiment, computer chip 100 includes processor and control circuits which are carried by a substrate and coupled together so that signals can flow between them. Computer chip 100 also includes a memory circuit positioned above the processor and control circuits. The memory circuit is spaced apart from the processor and control circuits by an interconnect region. The memory circuit is also coupled to the control circuit through the interconnect region so that signals can flow therebetween. In this way, the control circuit can receive output signals from the processor circuit and, in response, provide signals to and receive signals from the memory circuit. In response, the control circuit provides input signals to the processor circuit. It should be noted that a memory circuit is discussed here and throughout the disclosure for illustrative purposes and that, in other embodiments, the memory circuit can be replaced with other circuitry which can be fabricated in the same or a similar manner.

A processor circuit typically executes a series of machine instructions to process data. It usually includes an ALU (Arithmetic/Logic Unit) to perform mathematical operations like addition, subtraction, multiplication and division. Modern processor circuits typically include floating point processors that can perform extremely sophisticated operations on large floating point numbers. A processor circuit provide commands to the control circuit to move data from one memory location to another in the memory circuit. A processor circuit can also make decisions and jump to a new set of instructions based on those decisions.

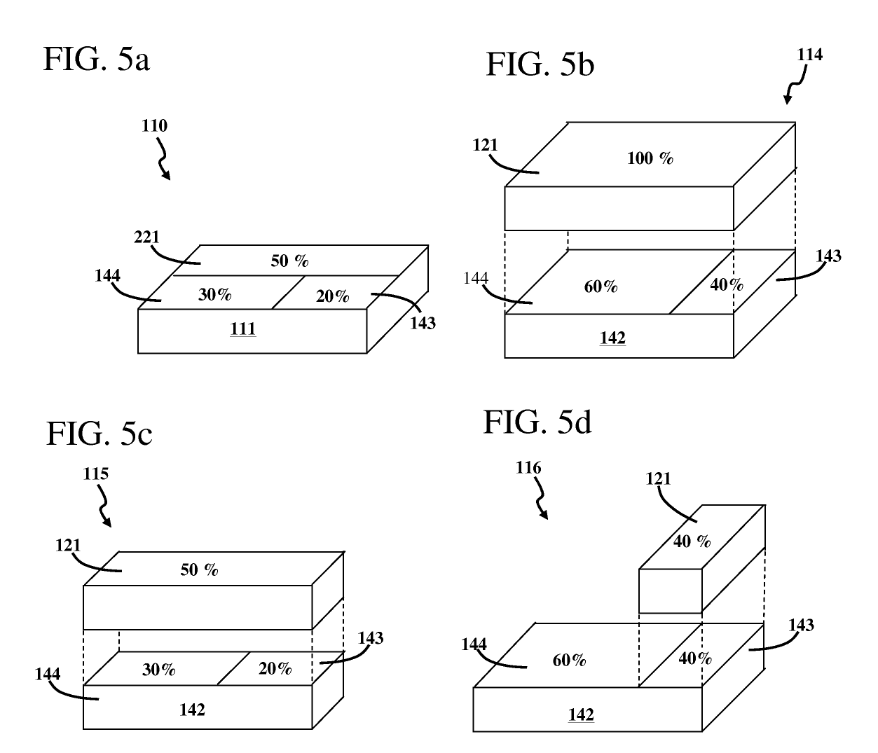

One advantage of computer chip 100 is that the memory circuit is positioned above the control and processor circuits which is desirable since the memory circuit typically occupies much more area than the control and processor circuits. In some examples of a typical computer chip where the processor, control, and memory circuits are positioned on the same substrate, the memory circuit can occupy 50% or more of the total area of the chip. An example of this is shown in FIG. 5a, which is a perspective view of a computer chip 110 with a memory circuit 221 positioned on the same substrate 111 as processor and control circuits 144 and 143. In this particular example, processor circuit 144 and control circuit 143 occupy 30% and 20%, respectively, of the total area of the chip, and memory circuit 221 occupies 50%. It should be noted, however, that they can occupy different amounts of area than that shown here.

FIGS. 5b-5d are simplified perspective views of computer chips 114, 115, and 116, respectively, which are similar or identical to computer chip 100. In FIGS. 5b-5d, computer chips 114, 115, and 116 each include a substrate 142 which carries processor circuit 144 and control circuit 143. Chip 100 also includes memory circuit 121 positioned above and separated from substrate 142 by an interconnect region, which is not shown for simplicity. In the example shown in FIG. 5b, processor circuit 144 and control circuit 143 include more electronic devices and occupy twice the area than they do in computer chip 110 shown in FIG. 5a. This may be desirable so that computer chip 114 can operate with data represented by a higher number of bits. This may also be desired so that chip 114 can perform more complicated operations, such as more accurate computations or pipelining. Further, memory circuit 121 also occupies twice the area so that it can store more information, which speeds up the operation of computer chip 114.

In FIG. 5c, the area of computer chip 115 is half the size of computer chip 110 shown in FIG. 5a because processor 144 and control circuit 143 are the same size as that shown in FIG. 5a. Memory circuit 121 is positioned above substrate 142 and extends over the same area as processor circuit 144 and control circuit 143 combined. In this way, computer chip 115 in FIG. 5c occupies half the area as chip 110 and, consequently, is less expensive to fabricate because it has a higher yield and more chips can be fabricated on a single wafer.

In FIG. 5d, the area of computer chip 116 is the same as computer chip 110 shown in FIG. 5a, but processor 144 and control circuit 143 are the same size as that shown in FIG. 5b. Memory circuit 121 is positioned above substrate 142 and extends over the same area as control circuit 143, so its size is less than that shown in FIG. 5b. This may be useful in applications where a lot of memory is not needed. It should be noted that memory circuit 121 can also be positioned over processor circuit 142 or it can extend over both processor and control circuits 144 and 143.

It should also be noted that in some embodiments, the processor in the computer chip discussed herein can address memory devices on a separate chip positioned outside the computer chip. Further, in some embodiments, the computer chip can include embedded memory cells on the same surface as the control and processor circuits, in addition to the memory devices positioned above them. These memory devices can include a cache memory and/or ROM devices. For example the ROM devices can operate as a BIOS (Basic Input/Output System) for the computer system.

Another advantage of computer chip 100 is that the memory circuit is positioned closer to the control and processor circuits so that signals can flow therebetween in less time. This speed up operation of computer chip 100 because the access time is reduced and computer chip 100 is idle for fewer cycle times. Still another advantage of circuit 100 is that the control and processor circuits are fabricated with a different mask set than the memory circuit. Hence, the masks are less complicated and less expensive to make. A further advantage is that the memory devices are fabricated from blanket semiconductor layers after they have been bonded to the interconnect region. Hence, the memory devices do not need to be aligned with the processor and/or control circuitry, which is a complicated and expensive process.

In this embodiment, computer chip 100 includes control circuit 143 and processor circuit 144 carried by substrate 142 (FIG. 4). Computer chip 100 also includes memory circuit 121 spaced apart from processor circuit 144 and control circuit 143 by an interconnect region 131. In this way, memory circuit 121 is positioned above processor circuit 144 and control circuit 143 as discussed above. Memory circuit 121 is coupled to control circuit 143 through interconnect region 131 so that signals can flow therebetween.

In this embodiment, substrate 142 includes silicon, although it can include other materials which can support the subsequent structures positioned thereon. Other suitable substrate materials include gallium arsenide, indium phosphide, and silicon carbide, among others. It should be noted that substrate 142 can have portions doped n-type or p-type and some portions of substrate 142 can even be undoped. The preferred material for substrate 142 in this invention is single crystalline material which can have defects, but is generally better material quality compared to amorphous or polycrystalline material.

In this example, control circuit 143 and processor circuit 144 include digital circuitry known in the art. However, the digital circuitry is not shown in FIG. 3 or 4 for simplicity and ease of discussion. The digital circuitry can include electronic devices, such as transistors, which extend into substrate 142 and/or out of substrate 142 through a surface 142a (FIG. 4). Processor circuit 144 can operate in many different ways. For example, processor circuit 144 can operate as a central processing unit, such as those commonly found in a computer chip, a signal processor, such as those commonly found in communication systems, or a microcontroller. In other examples, processor circuit 144 can include analog circuitry, such as amplifiers and/or converters, for analog-to-digital converter applications. Control circuit 143 includes circuitry typically found in periphery logic circuits which read, write, and erase semiconductor memory devices. This circuitry typically includes a sense amplifier, column selector, and/or a row selector which are used to communicate with memory devices, as will be discussed in more detail below.

As shown in FIG. 4, interconnect region 131 is positioned on surface 142a of substrate 142. Interconnect region 131 and regions subsequently positioned thereon are not shown in FIG. 3 for simplicity. Here, interconnect region 131 includes an interlayer dielectric region (ILD) 133 with interconnects extending between surface 142a and a surface 131a of region 131 so that signals can flow therethrough. Each interconnect typically includes one or more interconnect lines 135 and/or one or more vias 134. Interconnect region 131 also typically includes one or more contacts 132 coupled to the electronic devices included in control circuit 143 or processor circuit 144.

In this embodiment, the interconnects included in interconnect region 131 can be formed so that signals, such as signal Sₐ, can flow between the various devices included in processor circuit 144. The interconnects can also be coupled together so that signals can flow between control circuit 143 and processor circuit 144. The interconnects, vias, and contacts can include conductive materials known in the art, such as aluminum (Al), copper (Cu), tungsten (W), titanium (Ti), or a doped semiconductor, among others.

For example, signal Sₐ can flow between processor circuit 144 and control circuit 143 through an interconnect 138a included in interconnect region 131, as shown in FIG. 4. Interconnect 138a includes contacts 132a and 132b and an interconnect line 135a. Ends of contacts 132a and 132b are coupled to processor circuit 144 and control circuit 143, respectively, and extend upwardly therefrom surface 142a. Interconnect line 135a extends between opposed ends of contacts 132a and 132b. Here, control circuit 143 is positioned near processor circuit 144 so that the distance traveled by signals Sₐ flowing therebetween is reduced.

In this embodiment, a memory circuit 121 is positioned on interconnect region 131 and bonded to surface 131a. The bonding can be done in many different ways. For example, the bonding can be done by heating bonding surface 131a and coupling memory circuit 121 thereto. Since memory circuit 121 is bonded to interconnect region 131 instead of deposited thereon, it can include better quality semiconductor material. One reason the material is better quality is because it is more crystalline. It is more crystalline than polycrystalline material which is typically deposited on dielectric regions when wafer bonding is not used. More information about wafer bonding can be found in co-pending U.S. patent applications titled “SEMICONDUCTOR LAYER STRUCTURE AND METHOD OF MAKING THE SAME,” “SEMICONDUCTOR BONDING AND LAYER TRANSFER METHOD,” and “WAFER BONDING METHOD”, filed on an even date herewith by the same inventor and incorporated herein by reference.

Memory circuit 121 includes a bit line 120a positioned on surface 131a. A dielectric region 123 is positioned on surface 131a and bit line 120a. Bit line vias 124a extend upwardly therefrom bit line 120a and through dielectric region 123. The number of bit line vias 124a depends on the number of devices it is desired to form in memory circuit 121. Each bit line via 124a is coupled to an electronic device 124.

Electronic device 124 is typically a transistor or a memory device, although it can include other devices. The transistor can be a metal oxide semiconductor field effect transistor (MOSFET) and the memory device can be a negative differential resistance (NDR) static random access memory (SRAM) cell. An NDR SRAM includes a layer structure that operates as a transistor and a layer structure that operates as a thyristor. The transistor and thyristor are coupled together to operate as the NDR SRAM cell. More information regarding the NDR SRAM cell can be found in co-pending U.S. patent application titled “SEMICONDUCTOR MEMORY DEVICE” filed on the same date herewith by the same inventor and incorporated herein by reference.

A reference line via 124b is coupled to the opposite end of each device 124. Each reference line via 124b extends upwardly from its corresponding device 124 where it connects to a reference line 120b. In this way, each device 124 is coupled between bit line and reference lines vias 124a and 124b. It should be noted, however, that in other embodiments, line 120a can be used as a reference line and line 120b can be used as a bit line. A dielectric region 148 is positioned on dielectric region 123 and reference line 120b.

Memory circuit 121 and interconnect region 131 include interconnects so that signals can flow between control circuit 143 and bit line 120a and reference line 120b. In this particular example, a reference interconnect 136 extends through regions 133 and 123 so that one end is coupled to control circuit 143 and the opposite end is coupled to reference line 120b. Similarly, a bit interconnect 137 extends through region 133 so that one end is coupled to control circuit 143 and the other end is coupled to bit line 120a. Hence, control circuit 143 can provide a bit signal to bit line 120a through interconnect 137 and a reference signal to reference line 120b through interconnect 136. In this way, control circuit 143 can communicate with the devices included in device structure 124. In other examples, the reference line 120b can be connected to an outside contact (not shown) which provides a reference voltage or current from outside of the circuit 100.

In operation, various signals, such as signal Sₐ, can flow between processor circuit 144 and control circuit 143. In response, control circuit 143 provides signals to and receives signals from memory circuit 121 through interconnects 136 and 137. The signals can be to read, write, and/or erase information in memory circuit 121. Control circuit 143 then provides input signals to processor circuit 144. The input signals can be data values stored by memory circuit 121 that processor circuit 144 desires to process.

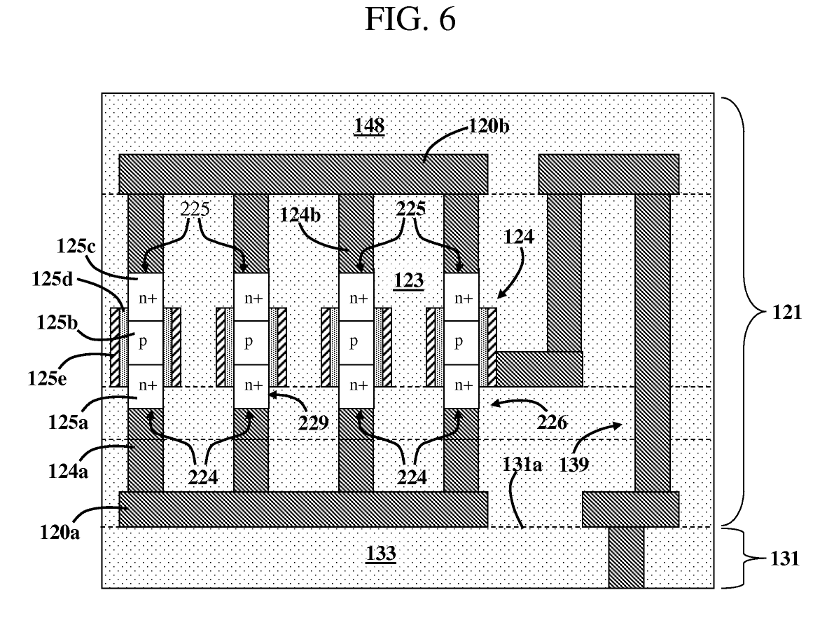

FIG. 6 is a more detailed sectional view of memory circuit 121. In this particular example, each electronic device 124 is a single transistor capacitorless dynamic random access memory (DRAM) device, although devices 124 can include other devices, such as a SONGS (Semiconductor Oxide Nitride Oxide Semiconductor) type nonvolatile memory device with a ONO (Oxide Nitride Oxide) dielectric. Here, device 124 includes an n⁺pn⁺ stack of layers, although it can include other layer structures, such as a npn stack, a p⁺np⁺ stack, or a pnp stack. The n⁺pn⁺ stack includes an n⁺-type doped region 125a positioned on bit line via 124a and a p-type doped region 125b positioned on region 125b. An n⁺-type doped region 125c is positioned on region 125c so that it is coupled between region 125b and reference line via 124b. An insulating region 125d is positioned around the outer periphery of the stack of regions 125a, 125b, and 125c. A control terminal 125e is positioned around the outer periphery of insulating region 125d.

In this way, the conductivity of regions 125a, 125b, and/or 125c can be adjusted in response to a word signal provided to control terminal 125e. The word signal is provided by control circuit 143 through a word interconnect 139. Word interconnect 139 is coupled between control circuit 143 and control terminal 125e and extends through dielectric regions 123 and 133 similar to interconnects 136 and 137. Interconnect 139, insulator region 125d, and control terminal 125e are not shown in FIG. 4 for simplicity.

It should be noted that, in this embodiment, device 124 includes a portion of substrate 223. In particular, device 124 includes opposed surfaces 224 and 225. In this particular embodiment, surfaces 224 and 225 are surfaces of regions 125a and 125c, respectively. In this embodiment, surface 225 is positioned away from bonding interface 226, and surface 224 is positioned proximate to bonding interface 226. It should be noted that the stack of semiconductor layers of electronic device 124 includes a sidewall 229 which extends between surfaces 224 and 225.

In some embodiments, surface 225 is planarized. In this way, region 125c includes a planarized surface. In some embodiments, surface 224 is planarized. In this way, region 125a includes a planarized surface. Further, in some embodiments, surfaces 224 and 225 are planarized. In this way, regions 124a and 125c each include planarized surfaces. It should be noted that surface 224 is planarized before bonding interface 226 is formed. In this way, the stack of semiconductor layers of electronic device 124 includes opposed planarized surfaces. In these embodiments, the stack of semiconductor layers of electronic device 124 includes a sidewall 229 which extends between opposed planarized surfaces 224 and 225.

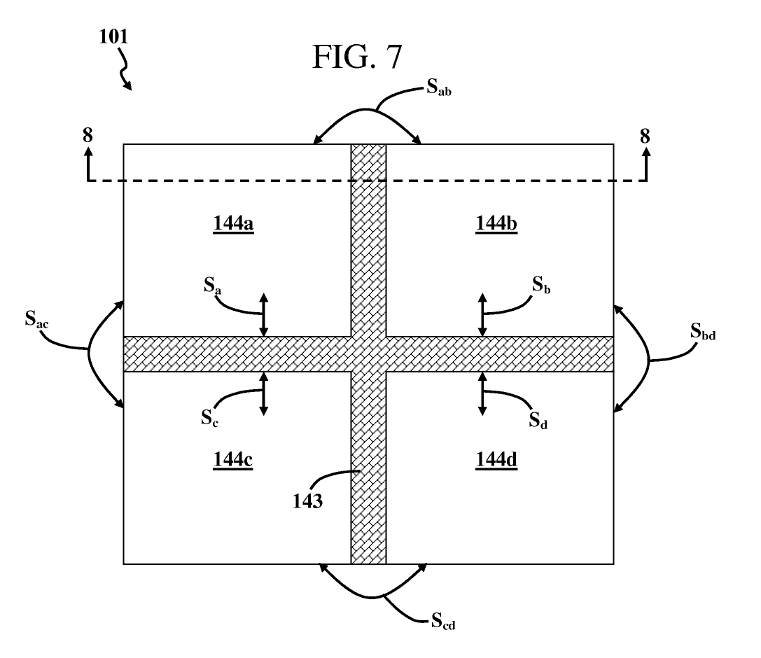

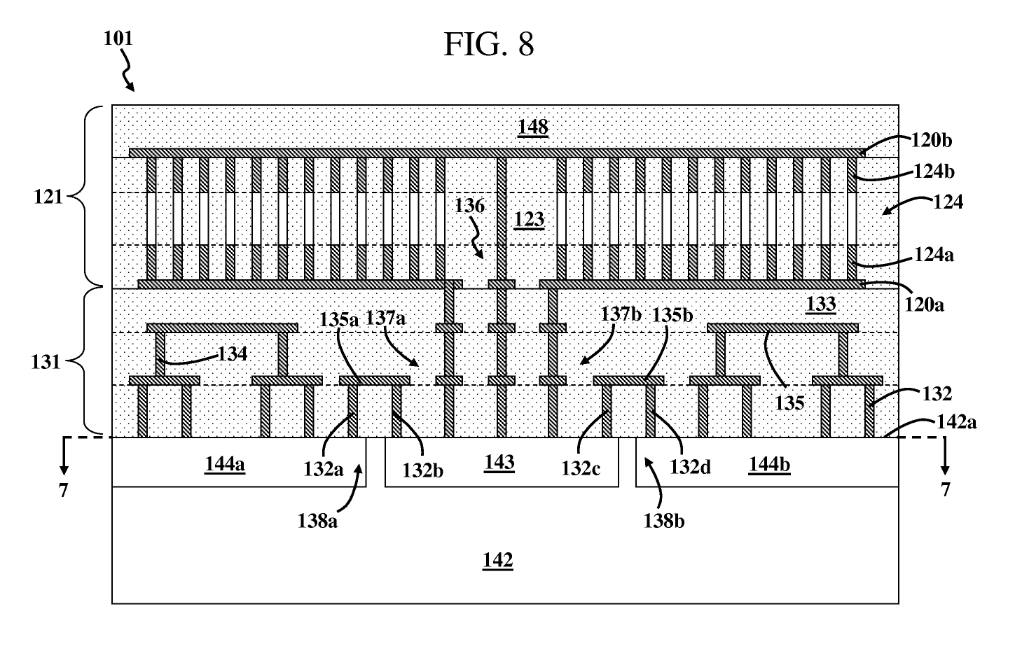

FIGS. 7 and 8 show simplified top and sectional views of a computer chip 101. FIG. 7 is a top view taken along a cut-line 5-5′ of FIG. 8 and FIG. 8 is a sectional view taken along a cut-line 6-6′ of FIG. 7. In this embodiment, chip 101 includes multiple processors which can communicate with the control circuit and the memory circuit as discussed above in conjunction with FIGS. 3-4, 5b-5d, and 6. In this embodiment, however, the processors can also communicate with each other using an interface circuit (not shown) which provides better data flow between processors. The data flow is better because it can happen faster and with less noise so there are fewer errors in the signal.

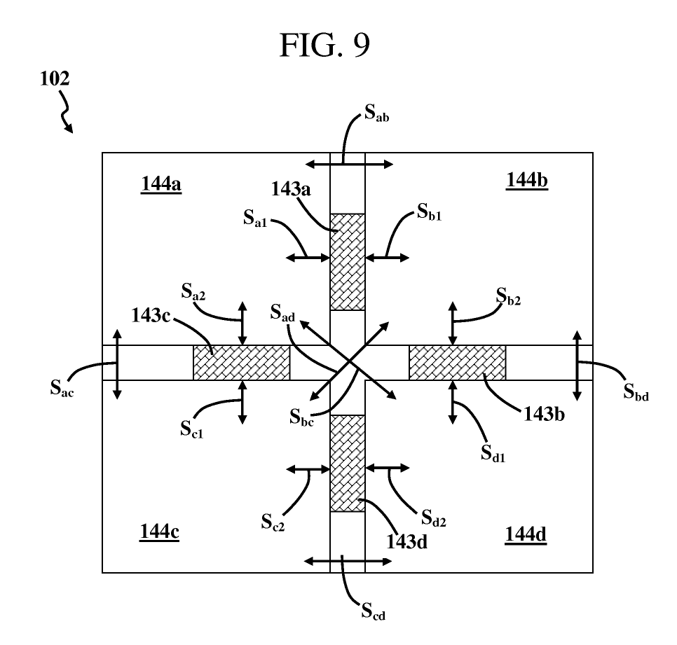

Computer chip 102 includes control circuit 143 and processors 144a-144d which are carried by substrate 142 (FIG. 8). Here, control circuit 143 is positioned in a region that is cross-shaped from a top view (FIG. 9) so that it extends between processors 144a-144d. In this way, the processors are separated from each other by control circuit 143. It should be noted that in this example, processors 144a-144d can be the same or similar to processor circuit 144 discussed above in conjunction with FIGS. 3-4, 5b-5d, and 6. Interconnect region 131 is positioned on surface 142a of substrate 142 so that it covers control circuit 143 as well as processors 144a-144d. However, in other embodiments, interconnect region 131 can be positioned so that it covers only a portion of logic circuit 143, processor circuit 144a, processor circuit 144b, processor circuit 144c, and/or processor circuit 144d.

In chip 101, various signals can flow between processors 144a-144d and control circuit 143. For example, signal Sₐ, S_{b}, S_{c}, and S_{d} can flow between processor circuit 144a, 144b, 144c, and 144d, respectively, and control circuit 143, as shown in FIG. 7. Signals can also flow between processors 144a-144d without flowing through control circuit 143. For example, signals S_{ab}, S_{ac}, S_{bd}, and S_{cd} can flow between processors 144a-144b, 144a-144c, 144b-144d, and 144c-144d, respectively, as shown in FIG. 7. Signals S_{ab}, S_{ac}, S_{bd}, and S_{cd} can flow through interconnects which extend through interconnect region 131. The interconnects can be similar to interconnect 138, but are not shown for simplicity.

In a particular example, signal Sₐ can flow between processor circuit 144a and control circuit 143 through an interconnect 138a, as shown in FIG. 8. Interconnect 138a includes contacts 132a and 132b and interconnect line 135a, as described above in conjunction with FIG. 4. Similarly, signal S_{b} can flow between processor circuit 144b and control circuit 143 through an interconnect 138b. Interconnect 138b includes contacts 132c and 132d and interconnect line 135b. Ends of contacts 132c and 132d are coupled to processor circuit 144b and control circuit 143, respectively, and extend upwardly therefrom. Interconnect line 135b extends between opposed ends of contacts 132c and 132d so that signal S_{b} can flow between processor circuit 144b and control circuit 143. Signals S_{c} and S_{d} can flow between control circuit 143 and corresponding processors 144c and 144d with similar interconnects included in interconnect region 131.

One advantage of chip 101 is that the distance between control circuit 143 and processors 144a-144d is reduced so that they can communicate with each other faster. This increases the speed of computer chip 100. Another advantage is that the design of chip 101 is convenient because each processor circuit 144a-144d can have the same or a similar design which simplifies its fabrication.

FIG. 9 is a top view of another embodiment of a computer chip, which is denoted as computer chip 102. Chip 102 includes processors 144a-144d positioned near each other in a manner similar to that of chip 101 shown in FIG. 7. Here, however, the control circuit includes separate control circuits 143a-143d. In this example, processors 144a and 144b are spaced apart by control circuit 143a, processors 144b and 144d are spaced apart by control circuit 143b, processors 144a and 144c are spaced apart by control circuit 143c, and processors 144c and 144d are spaced apart by control circuit 143d. It should be noted that each control circuit 143a-143d can be the same or similar to control circuit 143 shown in FIG. 6.

Here, signals Sₐ₁ and S_{b1} flow between control circuit 143a and processors 144a and 144b, respectively. Signals Sₐ₂ and S_{c1} flow between control circuit 143c and processors 144a and 144c, respectively. Signals S_{b2} and S_{d1} flow between control circuit 143b and processors 144b and 144d, respectively. Signals S_{c2} and S_{d2} flow between control circuit 143d and processors 144c and 144d, respectively.

Signals Sₐ₁, S_{b1}, Sₐ₂, S_{c1}, S_{b2}, S_{d1}, S_{c2}, and S_{d2} flow between corresponding control circuits and processors through interconnects, similar to interconnects 138a and 138b, as described above, in conjunction with FIG. 8. Signals S_{ab}, S_{ac}, S_{bd}, S_{ad}, S_{bc}, and S_{cd} flow between corresponding processors 144a-144d through conductive lines which extend through substrate 142 or on its surface 142a. However, these conductive lines are not shown for simplicity. One advantage of chip 102 is that signals S_{ab}, S_{ac}, S_{bd}, S_{cd}, S_{ad}, and S_{bc}, can flow therebetween processors 144a-144d faster so that chip 102 can operate faster. One reason the signals can flow faster is because the interconnects are shorter so the distance of travel is shorter and their capacitance is smaller.

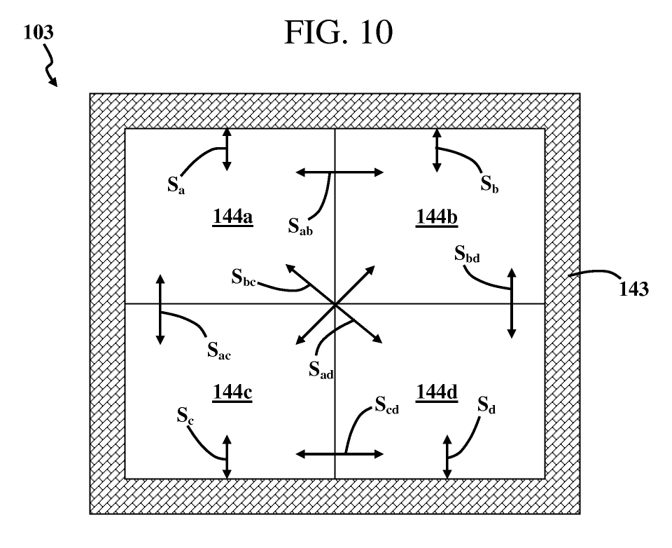

FIG. 10 is a top view of another embodiment of a computer chip, which is denoted as computer chip 103. Chip 103 includes processors 144a-144d positioned adjacent to each other. However, in this example, control circuit 143 extends around an outer periphery of processors 144a-144d. In this way, processors 144a-144d are surrounded by control circuit 143. Signals Sₐ, S_{b}, S_{c}, and S_{d} can flow between control circuit 143 and corresponding processors 144a-144d through interconnects, similar to interconnects 138a and 138b, as described above, in conjunction with FIG. 8. Similarly, processors 144a-144d are coupled together so that signals S_{ab}, S_{ac}, S_{bd}, S_{ad}, S_{bc}, and S_{cd} can flow therebetween as described above in conjunction with FIG. 9 above.

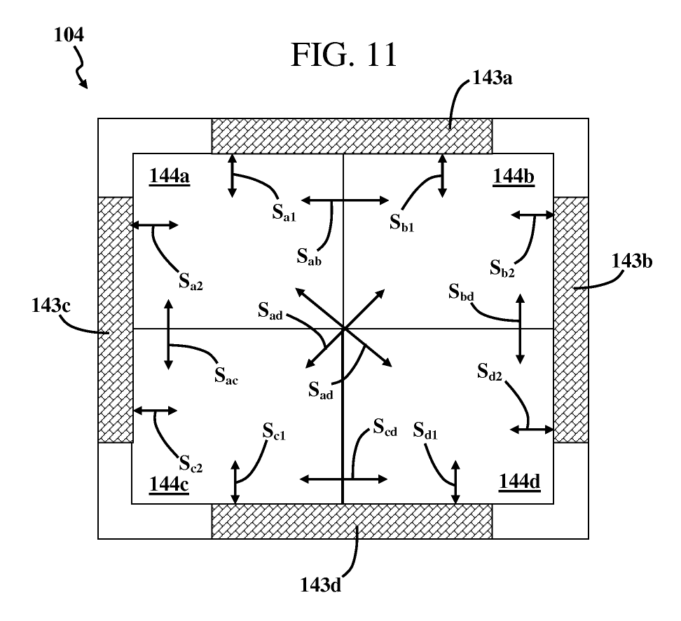

FIG. 11 is a top view of another embodiment of a computer chip, which is denoted as computer chip 104. Chip 104 includes processors 144a-144d positioned near each other in a manner similar to that of chip 103 shown in FIG. 10. Here, however, control circuit 143a extends along an outer periphery of processors 144a and 144b. Similarly, control circuit 143b extends along an outer periphery of processors 144b and 144d. Control circuit 143c extends along an outer periphery of processors 144a and 144c and control circuit 143d extends along an outer periphery of processors 144c and 144d.

Signals Sₐ₁, Sₐ₂, S_{b1}, S_{b2}, S_{c1}, S_{c2}, S_{d1}, and S_{d2} can flow between corresponding control circuits 143a-143d and corresponding processors 144a-144d through interconnects, similar to interconnects 138a and 138b, as described above, in conjunction with FIG. 8. Similarly, processors 144a-144d are coupled together so that signals S_{ab}, S_{ac}, S_{bd}, S_{ad}, S_{bc}, and S_{cd} can flow therebetween as described above in conjunction with FIG. 8 above.

The embodiments of the invention described herein are exemplary and numerous modifications, variations and rearrangements can be readily envisioned to achieve substantially equivalent results, all of which are intended to be embraced within the spirit and scope of the invention.

1. Circuitry, comprising: a first circuit;
an interconnect region, which includes a first interconnect; and
a second circuit coupled to the interconnect region through a bonding interface, the second circuit including a stack of semiconductor layers;
wherein the first and second circuits are in communication with each other through the bonding interface.

2. The circuitry of claim 1, wherein the stack of semiconductor layers includes crystalline semiconductor material.

3. The circuitry of claim 1, further including a third circuit positioned proximate to the first circuit so that the second circuit is spaced from the first and third circuits by the interconnect region.

4. The circuitry of claim 3, further including a second interconnect extending through the interconnect region, the first and third circuits being in communication with each other through the second interconnect.

5. The circuitry of claim 1, wherein the stack of semiconductor layers includes a planarized surface which faces the bonding interface.

6. The circuitry of claim 1, further including a semiconductor substrate which carries the first circuit.

7. Circuitry, comprising:
a substrate;
control circuitry carried by the substrate;
processor circuitry carried by the substrate;
an interconnect region which provides communication between the processor and control circuitry; and
memory circuitry carried by the interconnect region, the memory circuitry including a stack of semiconductor layers, wherein the stack includes a first planarized surface which faces the interconnect region.

8. The circuitry of claim 7, wherein the interconnect region provides communication between the memory circuitry and control circuitry.

9. The circuitry of claim 7, further including a bonding interface positioned between the memory circuitry and interconnect region.

10. The circuitry of claim 9, wherein the first planarized surface faces the bonding interface.

11. The circuitry of claim 7, wherein the stack includes a second planarized surface.

12. The circuitry of claim 11, wherein current flow through the stack of semiconductor layers is through the first and second planarized surfaces.

13. The circuitry of claim 11, wherein the stack of semiconductor layers includes a sidewall which extends between the first and second planarized surfaces.

14. Circuitry, comprising:
a substrate;
first and second processor circuits carried by the substrate;
a control circuit carried by the substrate;
an interconnect region carried by the substrate, the interconnect region allowing the first and second processor circuits to communicate with each other and the control circuit; and
a memory circuit in communication with the control circuit through the interconnect region, the memory circuit including a planarized surface which faces the interconnect region.

15. The circuitry of claim 14, wherein the memory circuit is spaced apart from the control circuit and the first and second processor circuits by the interconnect region.

16. The circuitry of claim 14, wherein the memory circuit is in communication with the first and second processor circuits through the control circuit.

17. The circuitry of claim 14, wherein the control circuit flows signals to and from the memory circuit, and the first and second processor circuits.

18. The circuitry of claim 14, wherein the control circuit is positioned between the first and second processor circuits.

19. The circuitry of claim 14, wherein the control circuit extends around a portion of the outer periphery of the first and second processor circuits.

20. The circuitry of claim 14, wherein the memory circuit includes a crystalline semiconductor material region.
